(19) United States
(12) Patent Application Publication
(10) Pub. No.: US 2004/0183015 A1
(43) Pub. Date: Sep. 23, 2004

(54) Methods for measuring dimensions of minute structures and apparatus for performing the same

(75) Inventors: Joon-Sung Kim, Gunpo-si (KR); Seok-Hwan Oh, Yongin-si (KR)

Correspondence Address: Frank Chau, Esq., F. CHAU & ASSOCIATES, LLC, 1900 Hempstead Turnpike, East Meadow, NY, 11554, US

(73) Assignee: SAMSUNG ELECTRONICS CO., LTD.

(21) Appl. No.: 10/802,982

(22) Filed: Mar. 17, 2004

(30) Foreign Application Priority Data
Mar. 17, 2003 (KR) 2003-16479

(51) Int. Cl. H01J 37/28; G01N 23/225

(52) U.S. Cl. 250/310; 250/307

(57) ABSTRACT

A method for measuring dimensions of minute structures on a substrate include irradiating primary electrons onto the minute structures, and detecting secondary electrons generated from the minute structures. Image data of the minute structures is formed, and at least two measuring regions are determined over the minute structures using the image data. The dimensions of the minute structures corresponding to the measuring regions are calculated. The primary electrons are provided from an electron emission member to the minute structures, and the secondary electrons are converted into current signals and then imaged in a displaying member. An operation member calculates the dimensions of the minute structures corresponding to the measuring regions using the image data of the minute structures stored in a storage member and measurement data that is measured at the measuring regions.

### BACKGROUND

1. Technical Field of the Invention

This disclosure relates to a method and apparatus for measuring dimensions of minute structures and an apparatus for performing the same. More particularly, the present disclosure relates to a method and apparatus for measuring dimensions of minute structures with a reduced measuring time, high throughput and increased reliability and an apparatus for performing the same.

2. Discussion of Related Art

In semiconductor devices, dimensions of or intervals between minute structures such as lines, spaces, contact holes or patterns have been decreased to achieve higher integration, which in turn allows for quicker data processing. However, minute structures that are imprecisely formed are prone to failure, thereby affecting subsequent fabrication processes and increasing defects in the completed semiconductor device. Hence, it is important to form the minute structures with precise dimensions. Further, measurement of the dimensions of the minute structures is required to ensure precise formation of the minute structures, before and/or after forming each minute structure.

Generally, characteristics of patterns on a semiconductor substrate vary in accordance with the method used to form a thin film on the semiconductor substrate. Methods for forming a thin film on a semiconductor substrate are divided into two types: physical vapor deposition (PVD) processes and chemical vapor deposition (CVD) processes. In a physical vapor deposition process, a heater provided with a source material to be deposited is positioned in a chamber under a high vacuum condition, and a wafer is positioned in the chamber apart from the heater. When the source material is heated to a high temperature by the heater, the source material is vaporized and then solidified on the wafer so as to form a thin film.

In a chemical vapor deposition process, a single crystalline semiconductor layer or an insulation layer is formed on a semiconductor substrate by a chemical reaction of the source material. Chemical vapor deposition processes are classified into low pressure chemical vapor deposition (LPCVD) processes, atmospheric pressure chemical vapor deposition (APCVD) processes, plasma enhanced chemical vapor deposition (PECVD) processes and high pressure chemical vapor deposition (HPCVD) processes, based on the pressure of the reaction chamber. Currently, chemical vapor deposition processes are used to deposit various kinds of thin films such as an amorphous silicon layer, a silicon oxide layer, a silicon nitride layer or a silicon oxynitride layer on a semiconductor substrate.

A lithography process is one example of a process that requires measuring the dimensions of patterns formed on a semiconductor substrate. In a lithography process, a series of masks are used in a series of continuous processes. Each mask has patterns corresponding to circuit elements that will be formed on a semiconductor substrate. The masks are used to pattern a photoresist layer on a thin film such as an insulation layer or a conductive layer on the semiconductor substrate. An exposure device such as a scanner or a stepper is used to project the patterns on the photoresist layer. The photoresist layer is exposed and then developed to form a photoresist pattern. The conductive layer or insulation layer is etched using the photoresist pattern as an etch mask to form minute structures such as a wiring, a conductive pattern or a hole.

Lithography processes are divided into two types: optical lithography processes and radiation lithography processes. An optical lithography process uses a shadow printing process or a projection printing process. Shadow printing processes are classified into contact printing processes in which a mask contacts the semiconductor substrate, and proximity printing processes in which a mask is apart form the semiconductor substrate.

A contact printing process gives high resolution results. However, the semiconductor substrate and possibly the photoresist pattern may be damaged by dirt or silicon particles. In a proximity printing process, the mask is typically not damaged because it is spaced apart from the semiconductor substrate by about 10 to about 15 μm. However, proximity printing processes produce poor resolution due to light diffraction between the mask and the semiconductor substrate. In a projection printing process, the mask is not damaged and the resolution is improved since only a small portion of the mask is exposed.

In a photolithography process, the photoresist layer has an exposure region onto which light is irradiated and a non-exposure region onto which light should not be irradiated. In some instances, light is irradiated from the side of the light sources, as well as from the center of the light source. When light is irradiated from the side of the light source, some regions of the photoresist layer that should not be exposed may be exposed. Further, when light is irradiated from the center of the light source, the incidence angles of light are substantially identical, and the photoresist pattern is formed with a uniform resolution. When light is irradiated from the side of the light source, the incidence angles of light may not substantially identical, and the resulting photoresist pattern may not be uniform.

When a lower layer such as an insulation layer or a conductive layer is etched using a non-uniform pattern, the critical dimension of the resulting conductive layer or insulation layer is also not uniform. Thus, as discussed above, a failure may occur during subsequent processes.

The critical dimension (CD) represents the minimum space or width between lines in a semiconductor device. When patterns are formed to fit into the critical dimension, overlapping or interference of wirings or lines may be prevented. However, lithography processes may result in patterns having imprecise dimensions, which in turn may cause problems in subsequent semiconductor device fabrication processes. Thus, precision of minute structures including patterns on the semiconductor substrate must be ensured before performing subsequent processes.

FIGS. 1A and 1B are electron microscope photographs illustrating a conventional method of measuring the dimensions of a pattern on a substrate. FIG. 1A is an electron microscope photograph illustrating a process for determining a first measuring region of the pattern. FIG. 1B is an electron microscope photograph illustrating a process for determining a second measuring region of the pattern.

Referring to FIGS. 1A and 1B, a plurality of patterns 10 is formed on the semiconductor substrate 5. The patterns 10 are formed substantially parallel or perpendicular with one another on the substrate 5. When the interval between the patterns 10 on the semiconductor substrate 5 is large, the dimension of one of the patterns 10 is measured. When the interval between the patterns 10 is small, dimensions of a plurality of patterns 10 should be measured.

A measuring region of the patterns 10 should be set before measuring of the dimensions of the patterns 10. In the conventional method, for example, a first measuring region A is calculated before measuring the dimensions of the patterns 10 corresponding to the first measuring region A and then a second measuring region B is calculated before measuring the dimensions of the patterns 10 corresponding to the second measuring region B. The image data of the patterns 10 is obtained by scanning the patterns 10. Then, the dimension of the pattern 10 corresponding to one of the measuring regions, for example the first measuring region A, is calculated. Subsequently, the image data of the patterns 10 is reloaded. The dimension of the pattern 10 corresponding to another measuring region, for example the second measuring region B, is calculated. The time for loading the image of the patterns is increased in direct proportion to the number of measuring regions. For example, when the number of measuring regions of the patterns 10 increases by about 10 times per each wafer, the time for measuring the dimensions of the patterns 10 increases by about 10 times. This time increase affects the overall semiconductor manufacturing process by decreasing throughput and increasing manufacturing cost.

### SUMMARY OF THE INVENTION

A method for measuring dimensions of minute structures according to an embodiment of the invention includes irradiating primary electrons onto minute structures. Image data of the minute structures is provided by detecting secondary electrons generated from the minute structures. At least two measuring regions are determined over the minute structures using the image data, and the dimensions of the minute structures corresponding to the measuring regions are calculated. The minute structures include at least one of a line, a hole, a trench or a space formed on a semiconductor substrate. The measuring regions are determined by mapping a boundary movable along an X-axis and a Y-axis on the image data. An apparatus for measuring dimensions of minute structures according to an embodiment of the invention includes an electron emission member, a display member, a storage member and an operation member. The electron emission member irradiates primary electrons onto the minute structures. The display member forms image data from secondary electrons generated from the minute structures, and determines at least two measuring regions over the minute structures. The storage member stores the image data and measurement data measured at the measuring regions. The operation member calculates the dimensions of the minute structures at the measuring regions.

A method for measuring dimensions of minute structures according to another embodiment of the invention includes providing image data of the minute structures, and forming an image of the minute structures using the image data. At least two measuring regions in the image are determined. Dimensions of the minute structures within each measuring region are calculated simultaneously.

### BRIEF DESCRIPTION OF THE DRAWINGS

Exemplary embodiments of the present invention will be described in detail with reference to the attached drawings in which:

FIG. 1A is an electron microscope photograph illustrating a process for determining a first measuring region in a conventional method for measuring dimensions of minute structures;

FIG. 1B is an electron microscope photograph illustrating a process for determining a second measuring region in a conventional method for measuring dimensions of minute structures;

FIG. 2 is a schematic block diagram illustrating an apparatus for measuring dimensions of minute structures according to an embodiment of the present invention;

FIG. 3 is a schematic perspective view illustrating an electron emission member, an image processing member and a monitor of the apparatus in FIG. 2;

FIG. 4 is an electron microscope photograph illustrating a process for determining measuring regions using the apparatus in FIG. 2; and

FIG. 5 is a flow chart illustrating a method for measuring dimensions of minute structures according to an embodiment of the present invention.

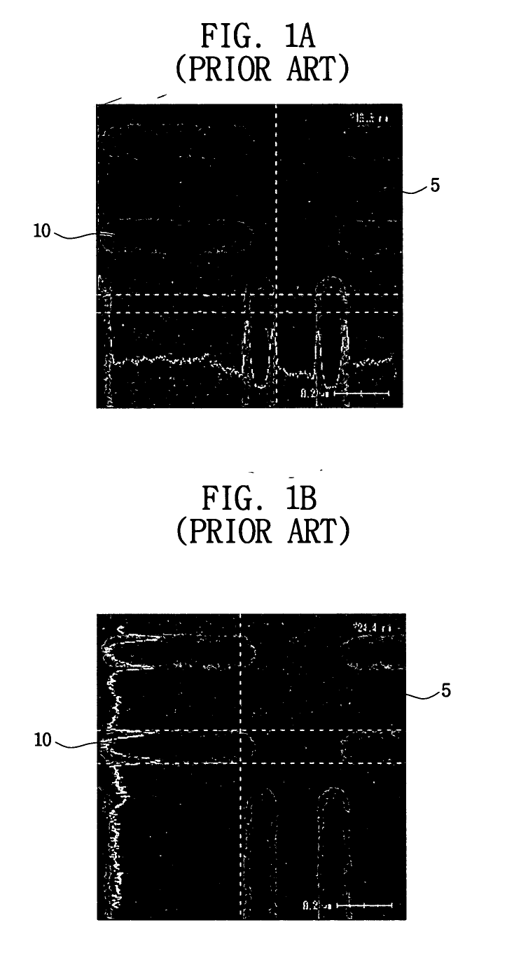

### DESCRIPTION OF PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like reference numerals refer to like elements throughout.

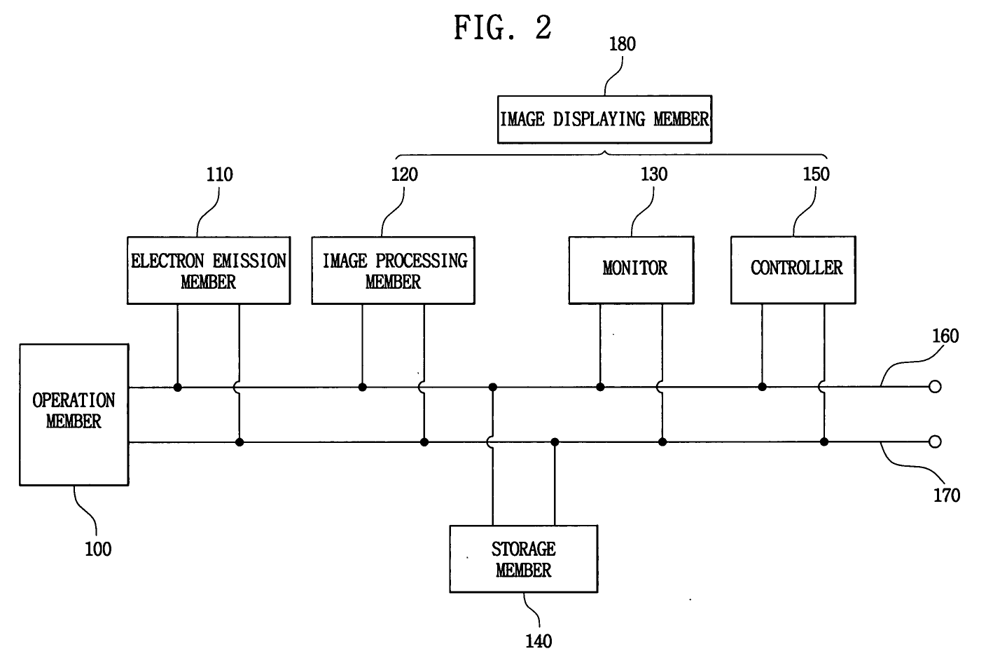

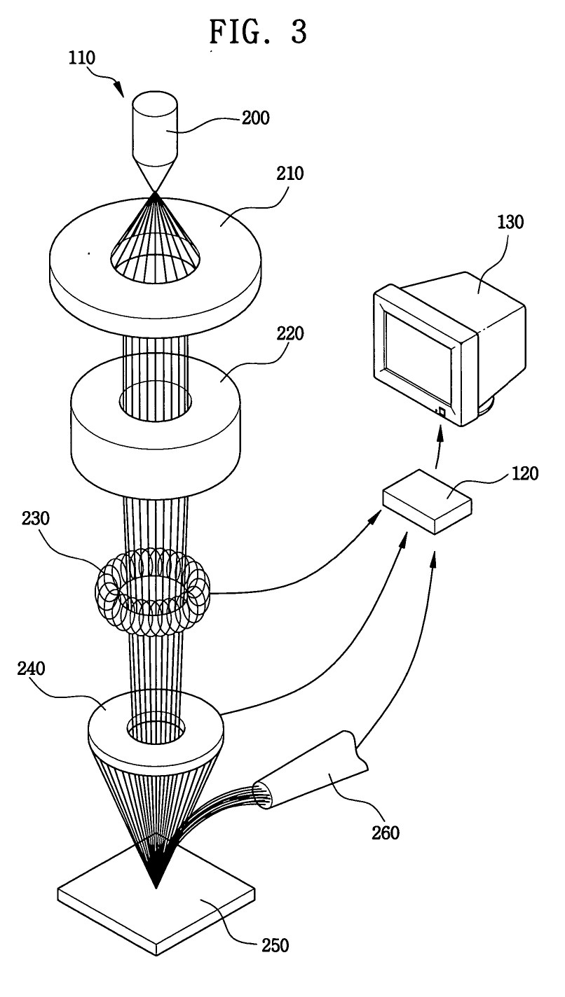

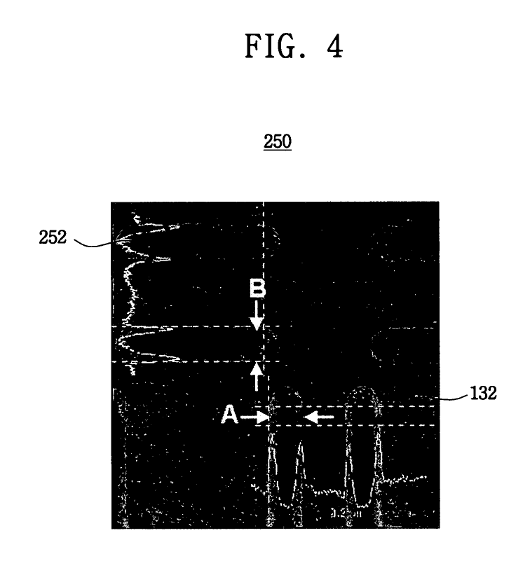

FIG. 2 is a schematic block diagram illustrating an apparatus for measuring dimensions of minute structures according to an embodiment of the invention. FIG. 3 is a schematic perspective view illustrating an electron emission member, an image processing member and a monitor of the apparatus in FIG. 2. FIG. 4 is an electron microscope photograph illustrating a process for determining measuring regions using the apparatus of FIG. 2.

Referring to FIGS. 2 to 4, the apparatus for measuring dimensions of minute structures according to the present embodiment of the invention includes an electron emission member 110, a displaying member 180, a storage member 140 and an operation member 100. The displaying member 180 includes an image processing member 120, a monitor 130 and a controller 150.

The electron emission member 110 irradiates primary electrons onto the minute structures 252 of an object 250 to be measured.

The image processing member 120 generates image data of the minute structures 252 from secondary electrons generated from the minute structures 252 of the object 250. The minute structures 252 of the object 250 include, for example, a line, a space or a contact hole. More particularly, the minute structures 252 may include a conductive pattern, insulation layer pattern or conductive wiring formed on a semiconductor substrate.

The storage member 140 stores the image data of the minute structures 252 and measurement data obtained from measuring regions.

The controller 150 determines at least two measuring regions in the minute structures 252 of the object 250.

The operation member 100 calculates the dimensions of the minute structures 252 corresponding to the measuring regions.

The operation member 100 is connected to the electron emission member 110, the image processing member 120, the monitor 130, the storage member 140 and the controller 150 for transmitting/receiving the image data or the measurement data of the minute structures 252 of the object 250. In particular, the operation member 100 is connected to the electron emission member 110, the image processing member 120, the monitor 130, the storage member 140 and the controller 150 through a data bus 160. The operation member 100 transmits/receives the image data of the minute structures 252 of the object 250 through the data bus 160. The operation member 100 is also connected to the electron emission member 110, the image processing member 120, the monitor 130, the storage member 140 and the controller 150 through a control bus 170. The operation member 100 transmits/receives the measurement data through the control bus 170.

Examples of the data bus 160 or the control bus 170 include an industry standard architecture (ISA) bus, an extended industry standard architecture (EISA) bus, a video electronics standards association (VESA) bus or a peripheral component interconnect (PCI) bus. A bus type may be selected according to a number of signals processed at a time.

As shown in FIG. 3, the electron emission member 110 includes an electron gun 200, an anode 210, a magnetic lens 220, a scanning coil 230, a first electron detector 240 and a second electron detector 260.

The electron gun 200 emits the primary electrons that will be irradiated onto the minute structures 252 of the object 250. The anode 210 discharges the primary electrons. The magnetic lens 220 focuses the primary electrons on the minute structures 252 of the object 250, and the scanning coil 230 synchronizes the primary electrons. The first electron detector 240 detects the primary electrons scattered from the minute structure 252 of the object 250. The second electron detector 260 detects the secondary electrons generated from the minute structure 252 of the object 250 after the primary electrons are irradiated onto the minute structure 252 of the object 250.

The primary electrons emitted from the electron gun 200 have energy of about 20 to about 30 keV. The primary electrons are discharged by the anode 210 and then move to the magnetic lens 220. The magnetic lens 220 focuses and irradiates the primary electrons on the minute structure 252 of the object 250. The primary electrons are synchronized on the image processing member 120 while passing through the scanning coil 230.

The focused primary electrons scan the surface of the object 250. The scanning coil 230 transmits the data of the scanned object 250 to the image processing member 120. The data of the scanned object 250 is used for displaying shapes of the minute structures 252 on the monitor 130.

The primary electrons emitted from the electron gun 200 collide with the surface of the object 250. Some of them are scattered from the surface of the object 250 and some of them are converted into secondary electrons. The secondary electrons are generated by an ionization reaction between the primary electrons and atoms of the object 250. The secondary electrons generated from the object 250 have energy of about 100 eV or less. The secondary electrons have different energy from each other in accordance with surface conditions of the object 250. When the minute structures 252 of the object 250 include a line, a hole, a trench or a space, for example, the secondary electrons generated from an inclined plane have energy different from that generated from an edge of the minute structures 252. The secondary electrons have higher energy at the inclined plane of the minute structures 252 than the secondary electrons at the top face of the minute structures 252. Additionally, the secondary electrons have higher energy at the edge of the minute structures 252 than the secondary electrons at the inclined plane of the minute structures 252. The region in where high-energy secondary electrons are formed has a brighter image on the monitor than other regions of the minute structures 252.

The secondary electrons generated from the surface of the object 250 are detected by the second electron detector 260. The second electron detector 260 is connected to the image processing member 120, and the image processing member 120 converts the secondary electrons into current signals. The secondary electrons are converted into different current signals in accordance with the secondary electron energy. The current signals converted from the secondary electrons are amplified and converted again into the image data of the minute structures 252. The image data is transmitted to the monitor 130 and the storage member 140.

Since the image data includes information about the surface shape of the minute structures 250 of the object 250, the shapes of the minute structures 252 on the object 250 are displayed on the monitor 130. The image data of the minute structures 252 of the object 250 are stored in the storage member 140. Later, the image data of the minute structures 252 are used to calculate the dimensions of the minute structures 252.

The primary electrons scattered from the surface of the minute structures 252 of the object 250 are detected by the first electron detector 240 connected to the image processing member 120. The scattering primary electrons provide information on the composition of the minute structures 252 of the object 250.

The image processing member 120 is connected to the monitor 130 through the data bus 160. The image of the minute structures 252 of the object 250 is displayed on the monitor 130. The shapes of the minute structures 252 on the object 250 are known from the image of the minute structures 252. Examples of the monitor 130 include a device for displaying an image based on the image data, such as a cathode ray tube (CRT) or liquid crystal display (LCD).

The controller 150 is connected to the monitor 130 and the operation member 100. As depicted in FIG. 4, a boundary 132 is displayed on the monitor 130. The boundary 132 is movable along a longitudinal X-axis, or a vertical Y-axis. The position of the boundary 132 is controlled on the monitor 130 by the controller 150. The boundary 132 is mapped with the image of the minute structures 252 on the monitor 130.

The boundary 132 is movable while mapping with the image of the minute structures 252. Thus, the boundary 132 is not necessarily displayed as a line. An electric signal such as a cursor or point that may easily determine the measuring regions of the minute structures 252 may be used.

The controller 150 includes an input member for controlling the movement of the boundary 132 on the monitor 130, such as, for example, a keyboard, a mouse, a trackball or a direction key. The measuring regions of the minute structures 252 are more easily determined using the input member of the controller 150.

The measuring regions of the minute structures 252 of the object 250 are determined while moving the boundary 132. At least two measuring regions are determined from one image of the minute structures 252 on the monitor 130. As shown in FIG. 4, when a first measuring region A and a second measuring region B are determined, the boundary 132 is moved either to the first measuring region A or to the second measuring region B using the controller 150. In particular, the boundary 132 is moved along the X-axis or the Y-axis to determine the measuring region between the first and second measuring regions A and B. Then, the coordinates of the boundary 132 are changed to a desired position so that another measuring region is determined. Various measuring regions may be determined by moving the boundary 132 along the X-axis or the Y-axis. The boundary 132 may include a plurality of boundaries along both the X-axis and the Y-axis.

The controller 150 also transmits information about the first and second measuring regions A and B to the operation member 100. The information about the first and second measuring regions A and B preferably includes X-axis and Y-axis coordinate values represented by binary numbers.

The operation member 100 connected to the displaying member 120 and the storage member 140 calculates the dimensions of the minute structures 252 by corresponding the image data of the minute structures 252 to the first and second measuring regions A and B. Particularly, the operation member 100 receives the image data, which has already been stored in the storage member 140, from the storage member 140. The operation member 100 calculates the dimensions of the minute structures 252 corresponding to the measuring regions A and B by corresponding the coordinate data of the measuring regions A and B received from the controller 150 to the image data.

When the image of the minute structures 252 of the object 250 is displayed on the monitor 130, the image of the minute structures 252 of the object 250 is also stored in the storage member 140. Accordingly, when the data of the measuring regions A and B set on one image of the minute structure 252 is transmitted to the operation member 100, the operation member 100 concurrently calculates the dimensions of the minute structures 252 corresponding to the measuring regions A and B. The image data of the minute structures 252 preferably has a frequency that allows for easy calculation of critical dimensions (CD) of the minute structures 252 of the object 250.

The operation member 100 transmits the data regarding the measurement to the monitor 130 and the storage member 140. The measurement data includes the dimensions of the minute structures 252. After the dimensions are calculated by the operation member 100, the calculated dimensions of the minute structures 252 are displayed on the monitor 130. When at least two measuring regions A and B are determined, the operation member 100 repeatedly transmits/receives the image data and measurement data of the minute structures 252 to the storage member 140 to calculate the dimensions of the minute structures 252 corresponding to the measuring regions A and B.

According to the present embodiment of the invention, a device for analyzing the image data of the minute structures 252 provided from the image processing member 120 is used as the operation member 100. The operation member 100 may include, for example, a boundary analysis device, a grey-scale analysis device, a frequency analysis device, a numeric operation processor, etc.

The storage member 140 may include, for example, a memory chip such as a random access memory (RAM), a programmable read only memory (PROM), an erasable programmable read only memory (EPROM) or a FLASH-EPROM, a magnetic recording media such as a cartridge, floppy disk, flexible disk, hard disk or magnetic tape, an optical recording media such as a compact disk-read only memory (CD-ROM) or digital versatile disk (DVD), or a physical recording media having a punched hole such as a punched card or paper tape.

The image data of the minute structures 252 includes dimension coordinates of the minute structures 252 and/or frequencies. The image data of the minute structures 252 preferably includes data useful for distinguishing the minute structures 252 formed on the object 250. The image data of the minute structures 252 may be stored in the storage member 140 before or after the dimensions of the minute structures 252 are calculated. In case that the apparatus according to the present invention is used in the preceding or following processes, optimal conditions may be set and throughput of the semiconductor manufacturing process increases.

The dimensions of the minute structures 252 are calculated by corresponding the image data of the minute structures 252 of the object 250 to the measuring regions A and B. The critical dimensions of the minute structures 252 on the semiconductor substrate are easily measured using the apparatus according to the present embodiment of the invention before or after a lithography or etching process. When the object to be measured has various shapes, such as lines, spaces and contact holes, each dimension corresponding to the measuring regions must be measured. The time for measuring the minute structures' dimensions is reduced by determining the measuring regions on one image. The image includes the minute structures without a repetitive image generating process for determining the measuring regions.

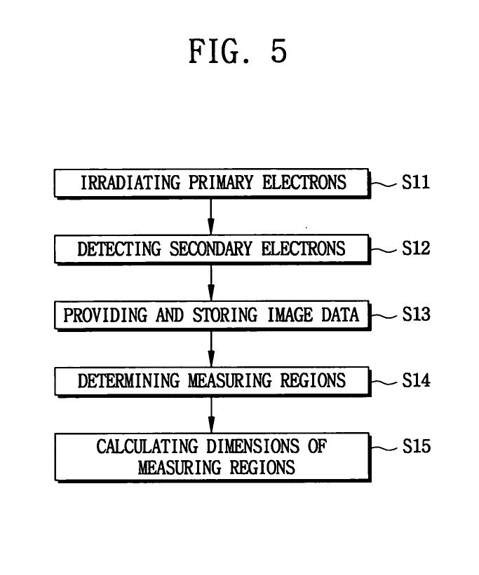

FIG. 5 is a flow chart illustrating a method for measuring dimensions of minute structures according to another embodiment of the present invention.

Referring to FIGS. 4 and 5, in step S11, primary electrons are irradiated onto an object 250 having minute structures 252 so as to scan the minute structures 252 of the object 250. In step S12, secondary electrons generated from a surface of the minute structures 252 of the object 250 by irradiating the primary electrons thereon are detected, and then the detected secondary electrons are converted into image data of the minute structures 252. In step S13, the image data of the minute structures 252 is provided to a displaying member and stored in a storage member. In step S14, at least two measuring regions A and B are determined using the image data of the minute structures 252 displayed in the displaying member. In step S15, the dimensions of the minute structures 252 corresponding to each of the measuring regions A and B are calculated and then transmitted to the storage member and the displaying member.

Hereinafter, a method for measuring dimensions of minute structures according to an embodiment of the present invention will be described in detail. The primary electrons are emitted from an electron emission member so as to calculate the dimensions of the minute structures 252 formed on the object 250. The primary electrons are focused on the minute structures 252 of the object 250. The primary electrons are synchronized on an image processing member 120 so as to scan the surface of the minute structures 252 of the object 250. The data of the scanned minute structure 252 is transmitted to the image processing member 120. The minute structures 252 of the object 250 may include a line, a hole, a trench, a space, etc.

The secondary electrons are generated from the primary electrons irradiated onto the minute structures 252 of the object 250. The secondary electrons are generated by an ionization reaction between the primary electrons and atoms of the object 250. The secondary electrons have different energy from each other in accordance with a surface shape of the object 250. The secondary electrons are detected and then converted into current signals. The secondary electrons are converted into current signals having different values according to the energy of the secondary electrons.

The current signals are amplified and then converted into image data of the minute structures 252. The image data of the minute structures 252 is transmitted to the displaying member 180 and stored in the storage member 140. The image data of the minute structures 252 includes information on the surface shapes of the minute structures 252. The shapes of the minute structures 252 of the object 250 are displayed in the displaying member 180 using the image data of the minute structures 252. The composition of the minute structures 252 is also known from the primary electrons scattered from the surface of the minute structures 252 of the object 250.

At least two measuring regions of the minute structures 252 are determined using the image data of the minute structures 252 displayed on the displaying member. Preferably, the measuring regions are determined using a boundary 132. The boundary 132 may be mapped with the image of the minute structures 252 displayed on the displaying member. The boundary 132 is movable on the displaying member. In exemplary embodiments of the invention, the boundary 132 is not necessarily displayed in a form of a line. For example, a cursor or point may be used as the boundary 132 to determine the measuring regions of the minute structures 252.

According to the present embodiment of the invention, a plurality of measuring regions are determined without having to reload the image data. For example, as shown in FIG. 4, when two regions are measured, one of the two measuring regions A and B is determined, and the other measuring region is then determined by changing the coordinates of the boundary 132 and moving the boundary 132. The measuring region is preferably set along an X-axis and a Y-axis using the boundary 132. The boundary 132 may include a plurality of boundaries displayed along the X-axis and the Y-axis.

The dimensions of the minute structures 252 are calculated by corresponding the image data of the minute structures 252 of the object 250 to the data of the measuring regions A and B using the operation member 100 and the storage member 140.

More particularly, the image data of the minute structures 252 stored in the storage member 140 is transmitted to the operation member 100. The image data of the minute structures 252 includes information on the coordinate values of the minute structures 252 formed on the object 250, and the measurement data includes information on the coordinate values of the measuring regions A and B. Accordingly, the dimensions of the minute structures 252 corresponding to the measuring regions A and B are calculated by corresponding the image data with the measurement data. Although at least two measuring regions such as A and B are determined, each dimension of the minute structures 252 can be calculated by repeating the dimension calculation operation. Thus, the dimensions of the minute structures 252 corresponding to the measuring regions A and B are simultaneously calculated. Accordingly, critical dimensions of the minute structures 252 on the semiconductor substrate can be easily measured before or after performing a photolithography or etching process.

After the dimensions of the minute structures 252 corresponding to the measuring regions A and B are calculated, the measurement data including the dimensions of the minute structures 252 is preferably stored in the storage member 140. The calculated dimensions can be provided to a user by a printer or the displaying member 180, and the image data and the measurement data are stored and utilized before or after each dimension of the minute structures 252 is calculated.

According to various exemplary embodiments of the invention, after at least two measuring regions are determined in one image of minute structures, image data of the minute structures is correlated with data of the measuring regions. Thus, each dimension of the minute structures is simultaneously calculated, thereby reducing time for measuring the dimensions of the minute structures. Additionally, the throughput of the overall semiconductor device manufacturing process increases, and manufacturing cost of the semiconductor device is reduced.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the invention as set forth in the following claims.

What is claimed is:

1. A method for measuring dimensions of minute structures comprising:
irradiating primary electrons onto the minute structures;
providing image data of the minute structures by detecting secondary electrons generated from the minute structures;
determining at least two measuring regions over the minute structures using the image data; and
calculating dimensions of the minute structures corresponding to the measuring regions.

2. The method of claim 1, wherein the minute structures comprise a line, a hole, a trench, a space or a combination thereof formed on a semiconductor substrate.

3. The method of claim 1, further comprising synchronizing the primary electrons to scan the minute structures after irradiating the primary electrons onto the minute structures.

4. The method of claim 1, wherein the secondary electrons are generated by an ionization reaction between the primary electrons and atoms of the minute structures.

5. The method of claim 1, wherein providing the image data comprises storing the image data in a storage member.

6. The method of claim 1, wherein providing the image data comprises converting the secondary electrons into current signals.

7. The method of claim 1, wherein determining at least two measuring regions comprises mapping a boundary movable along an X-axis and a Y-axis on an image generated from the image data.

8. The method of claim 1, wherein calculating the dimensions of the minute structures comprises correlating the image data to the measuring regions.

9. An apparatus for measuring dimensions of minute structures comprising:
an electron emission member for irradiating primary electrons onto the minute structures;
a display member for displaying image data formed by detecting secondary electrons generated from the minute structures, the display member determining at least two measuring regions over the minute structures;
a storage member for storing the image data and measurement data, the measurement data being obtained at the measuring regions; and
an operation member for calculating dimensions of the minute structures corresponding to the measuring regions.

10. The apparatus of claim 9, wherein the minute structures comprise a line, a space or a contact hole formed on a semiconductor substrate.

11. The apparatus of claim 9, wherein the electron emission member focuses the primary electrons on the minute structures, and synchronizes the primary electrons on the display member to scan the minute structures.

12. The apparatus of claim 11, wherein the electron emission member comprises:
an electron gun for emitting the primary electrons;
a magnetic lens for focusing the primary electrons on the minute structures;
a scanning coil for synchronizing the primary electrons;
a first electron detector for detecting the primary electrons scattered from the minute structures; and
a second electron detector for detecting the secondary electrons.

13. The apparatus of claim 9, wherein the operation member calculates the dimensions of the minute structures from the image data corresponding to the measuring region, and transmits the measurement data including the dimensions of the minute structures to the display member and the storage member connected thereto.

14. The apparatus of claim 9, wherein the display member comprises:
an image processing device for generating the image data;
a monitor for displaying the image data in a form of an image; and
a controller for determining the measuring regions, the controller being connected to the operation member.

15. The apparatus of claim 14, wherein the image processing device converts the secondary electrons into current signals to generate the image data.

16. The apparatus of claim 14, wherein the controller determines the measuring regions by mapping a movable boundary along an X-axis and a Y-axis with the image on the monitor, and transmits coordinate values of the measuring regions to the operation member.

17. The apparatus of claim 16, wherein the operation member calculates the dimensions of the minute structures by receiving a signal based on the measuring regions from the display member and by correlating the image data to the measuring region, and transmits the measurement data including the dimensions of the minute structures to the monitor and the storage member.

18. A method for measuring dimensions of minute structures comprising:
providing image data of the minute structures;
forming an image of the minute structures using the image data;
determining at least two measuring regions in the image; and
calculating dimensions of the minute structures within each measuring region simultaneously.

19. The method of claim 18, further comprising:
irradiating primary electrons onto the minute structures, wherein the step of providing image data of the minute structures includes detecting secondary electrons generated from the minute structures.

20. The method of claim 18, wherein the step of determining at least two measuring regions comprises mapping a boundary movable along an X-axis and a Y-axis on the image.
